(19) United States
(12) Patent Application Publication
(10) Pub. No.: US 2026/0011688 A1
(43) Pub. Date: Jan. 8, 2026

(54) ION IMPLANTATION FOR ETCH RATE REDUCTION DURING BACKSIDE CONTACT FORMATION

(71) Applicant: Applied Materials, Inc., Santa Clara, CA (US)

(72) Inventors: Yan ZHANG, Westford, MA (US); Sony VARGHESE, Manchester, MA (US)

(73) Assignee: Applied Materials, Inc., Santa Clara, CA (US)

(21) Appl. No.: 18/762,409

(22) Filed: Jul. 2, 2024

(51) Int. Cl. H01L 25/065; H01L 23/528; H01L 27/092; H01L 29/06; H01L 29/423; H01L 29/78

(52) U.S. Cl. CPC H01L 25/0652; H01L 23/5286; H10D 30/62; H10D 30/6735; H10D 62/121; H10D 84/85

(57) ABSTRACT

Approaches herein relate to methods for forming self-aligned backside contacts and metal sidewall contacts in a semiconductor device. One method may include forming a plurality of alternating first layers and second layers atop a base layer, forming a trench in the plurality of alternating first layers and second layers, and forming a source/drain epitaxial layer along a sidewall of the trench. The method may further include forming a recess in the base layer by extending the trench into the base layer following formation of the source/drain epitaxial layer, filling the recess with a temporary material, and performing an implant by directing ions to the source/drain epitaxial layer after filling the recess with the temporary material, wherein the implant increases an ion concentration along an outer surface of the source/drain epitaxial layer.

### FIELD OF THE DISCLOSURE

The present embodiments relate to semiconductor device patterning, and more particularly, to devices and methods for forming self-aligned backside contacts and metal sidewall contacts in a semiconductor device.

### BACKGROUND OF THE DISCLOSURE

As integrated circuit (IC) technologies progress towards smaller technology nodes, multigate devices have been used to improve gate control by increasing gate-channel coupling, reducing off-state current, and reducing short-channel effects. A multigate device generally refers to a device having a gate structure, or portion thereof, disposed over more than one side of a channel region. Field effect transistors (FETs) and gate-all-around (GAA) transistors, both also referred to as non-planar transistors, are examples of multigate devices that provide high performance and low leakage applications. The channel region of GAA transistors may be formed from nanowires, nanosheets (NS), or other nanostructures.

GAA and complementary FET (CFET) device performance is highly dependent upon the number of stacked NS. With conventional S/D contact schemes, a greater number of stacked NS increases the effects from S/D resistance, thus decreasing ring oscillator speed. Wrap-around-contacts can help reduce resistance with an enlarged contact area after trimming S/D epi. However, this benefit is NS-width dependent. Especially for narrow NS-width devices for which the resistance effects from side of S/D epi still exist, device performance becomes limited.

More recent S/D contact schemes for metal sidewall (MSW) contacts can enlarge the contact area and reduce resistance effects that enable larger stacked NS for device performance improvement. However, resistance levels are inadequate because of low doping along S/D epi/metal sidewall interface. Since MSW is closer to the channel region, conventional contact ion implants may degrade short-channel effects. In addition, the large aspect ratio (AR) from the increased number of NS and stacked devices like CFETs makes it difficult for conventional ion implants to achieve conformal doping along epi sidewalls due to shadowing effect. On the other hand, for continuous scaling, backside power distributed networks will be adopted, and contacts need to be formed from the backside (BSCON). The formation of a low contact resistance from the backside is challenging due to the low temperature limitation. Using MSW contact scheme for BSCON can help reduce the low-temp activation limitations since all contact dopants will be activated from frontside. Furthermore, BSCON metal can directly land on the MSW contact from the backside. However, misalignment between MSW contact and BSCON causes process variations and potentially electrical shorts between BSCON metal and the gate.

Accordingly, improved approaches are needed to form backside contacts and sidewall contacts for GAA-type devices and CFETs.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one aspect, a method may include forming a plurality of alternating first layers and second layers atop a base layer, forming a trench in the plurality of alternating first layers and second layers, and forming a source/drain epitaxial layer along a sidewall of the trench. The method may further include forming a recess in the base layer by extending the trench into the base layer following formation of the source/drain epitaxial layer, filling the recess with a temporary material, and performing an implant by directing ions to the source/drain epitaxial layer after filling the recess with the temporary material, wherein the implant increases an ion concentration along a surface of the source/drain epitaxial layer.

In another aspect, a method for forming a backside contact in a semiconductor device may include forming a trench in a plurality of alternating first layers and second layers, wherein the plurality of alternating first layers and second layers are formed atop a base layer, and forming a source/drain epitaxial layer along a sidewall of the trench, wherein the source/drain epitaxial layer is in contact with one or more of the plurality of alternating first layers and second layers. The method may further include forming a recess in the base layer by extending the trench into the base layer following formation of the source/drain epitaxial layer, filling the recess with a temporary material, and performing an implant by directing ions to the source/drain epitaxial layer after filling the recess with the temporary material, wherein the implant increases an ion concentration along an outer surface of the source/drain epitaxial layer. The method may further include removing the temporary material from the recess, and depositing a contact material within the recess to form the backside contact.

In yet another aspect, a method may include forming a trench in a nanosheet stack, the nanosheet stack comprising a plurality of alternating first layers and second layers, and forming a source/drain epitaxial layer along a sidewall of the trench. The method may further include etching the trench to form a recess in the base layer following formation of the source/drain epitaxial layer, forming a temporary material within the recess, and performing an implant by directing ions to the source/drain epitaxial layer after forming the temporary material, wherein the implant increases an ion concentration along an outer surface of the source/drain epitaxial layer. The method may further include performing a thermal process on the nanosheet stack and on the source/drain epitaxial layer after performing the implant.

### BRIEF DESCRIPTION OF THE DRAWINGS

The accompanying drawings illustrate exemplary approaches of the disclosure, including the practical application of the principles thereof, as follows:

FIGS. 1A-1K are cross-sectional views of a process for forming a GAA device structure according to embodiments of the present disclosure;

FIGS. 2A-2D are cross-sectional view of a process for forming a CFET device structure according to embodiments of the present disclosure;

FIG. 3 illustrates a perspective view of an exemplary plasma doping system, according to embodiments of the present disclosure; and

FIG. 4 illustrates a perspective view of an example processing system, according to embodiments of the present disclosure.

The drawings are not necessarily to scale. The drawings are merely representations, not intended to portray specific parameters of the disclosure. The drawings are intended to depict exemplary embodiments of the disclosure, and therefore are not to be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines otherwise visible in a “true” cross-sectional view, for illustrative clarity. Furthermore, for clarity, some reference numbers may be omitted in certain drawings.

### DETAILED DESCRIPTION

Methods, systems, and devices in accordance with the present disclosure will now be described more fully hereinafter with reference to the accompanying drawings, where various embodiments are shown. The methods, systems, and devices may be embodied in many different forms and are not to be construed as being limited to the embodiments set forth herein. Instead, these embodiments are provided so the disclosure will be thorough and complete, and will fully convey the scope of the methods to those skilled in the art.

With the adoption of backside power distributed networks (BSPDN) for advanced NS and CFETs, backside contacts (BSCON) are required for continuous cell height scaling. However, as compared to frontside contact (FSCON) schemes, contact resistance (Rc) reduction for BSCON is quite challenging due to the limited thermal budget. Additionally, the number of NS is still limited due to resistance issues for BSCON.

As will be described further herein, implementing a new MSW contact scheme for advanced NS and CFET technologies with BSPDN will improve BSCON formation by eliminating misalignment issues through the use of a placeholder. Embodiments of the present disclosure provide sidewall doping at room-temperature (RT), or higher, to reduce Rc in MSW contact for both FSCON and BSCON. At least the following advantages are provided by the solutions of the present disclosure. First, conformally doped S/D epi sidewalls have almost no limitation on AR or number of NS. Second, less doping induced defects are present with plasma doping (PLAD) processes, and thus less SCEs degradation is achieved. Third, subsequent thermal processing (e.g., annealing) steps from frontside process can activate dopants and thus reduce Rc. Fourth, MSW contact schemes with sidewall doping done from the device frontside is suitable for both FSCON and BSCON. This is especially beneficial for BSCON for which the Rc reduction is quite challenging due to temperature limitations.

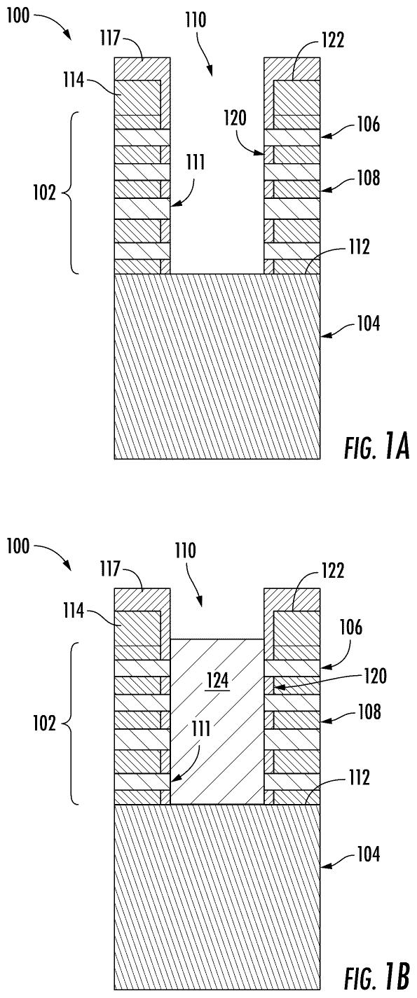

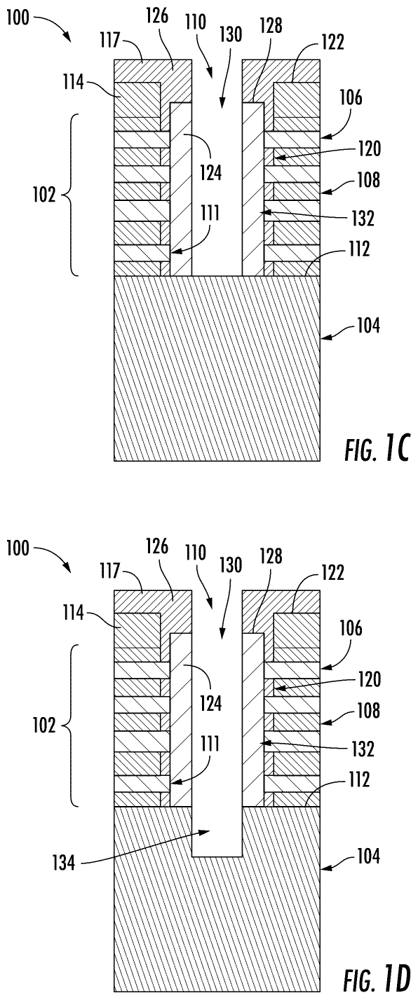

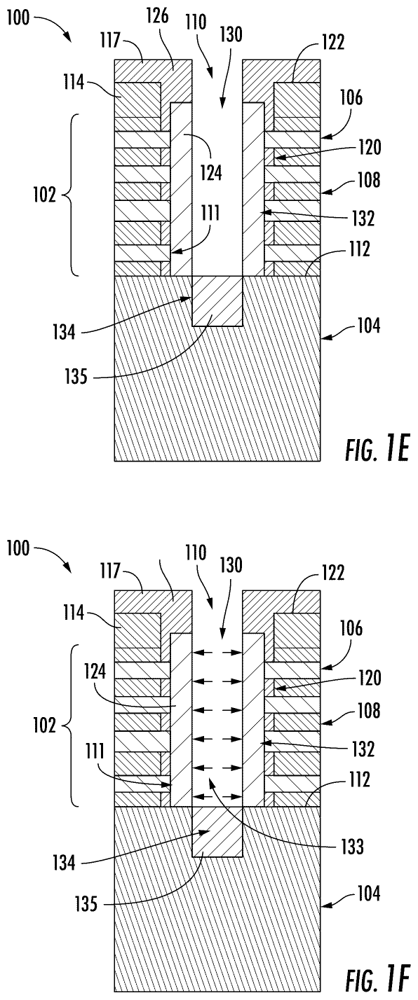

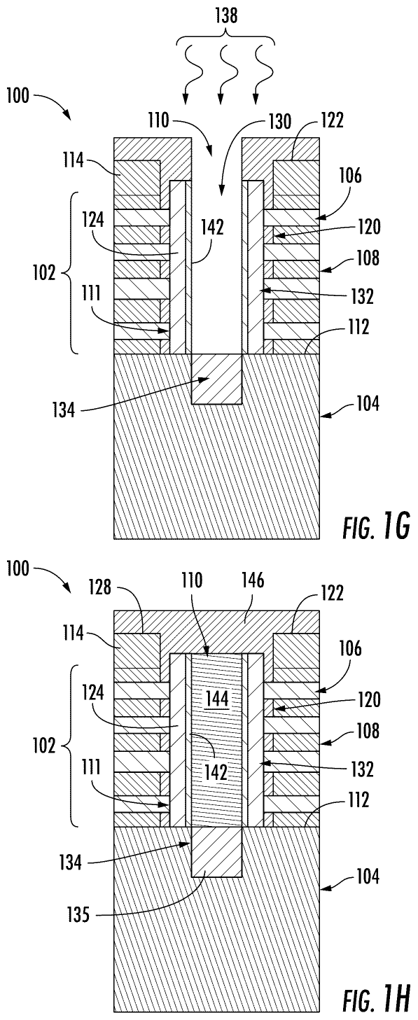

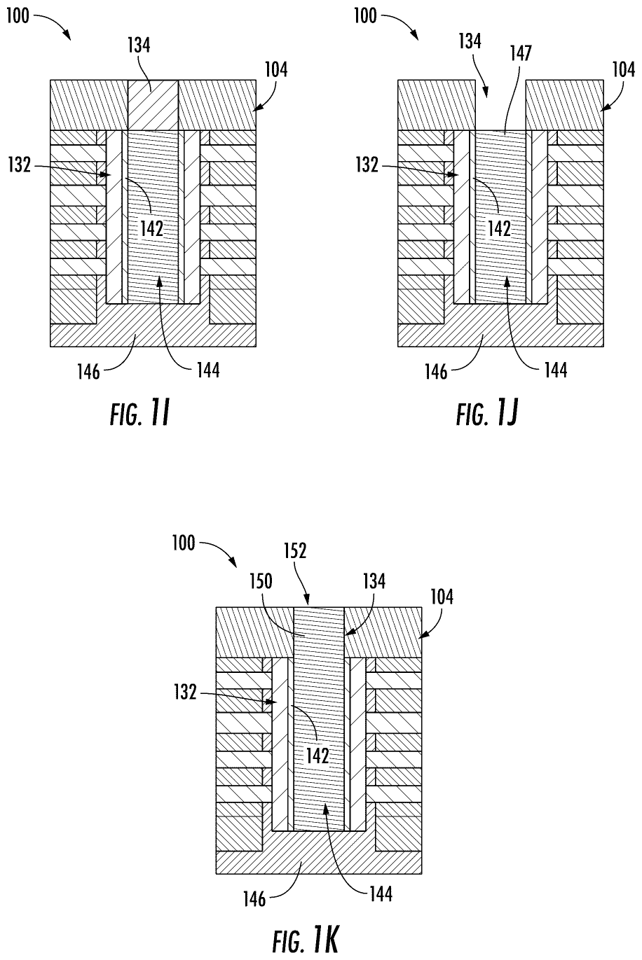

With reference to FIG. 1A, an approach for forming a semiconductor device (hereinafter “device”) 100 according to one or more embodiments will be described. Although non-limiting, the device 100 may be a GAA device structure, a vertical GAA device structure, or a horizontal GAA device structure. As shown, the device 100 may include a nanosheet stack 102 including a plurality of alternating first layers 106 and second layers 108 formed over a base layer 104.

The term ‘nanosheet,’ as used herein, refers to a sheet or a layer having nanoscale dimensions. Further, the term ‘nanosheet’ is meant to encompass other nanoscale structures such as nanowires. For instance, ‘nanosheet’ can refer to a nanowire with a larger width, and/or ‘nanowire’ can refer to a nanosheet with a smaller width, and vice versa.

In various embodiments, the plurality of alternating first layers 106 and second layers 108 may include between two (2) and ten (10) first layers 106 and between two (2) and ten (10) second layers 108. A composition of the first layers 106 may be different than a composition of the second layers 108 to achieve etching selectivity and/or different oxidation rates during subsequent processing, for example. In some embodiments, the plurality of alternating first layers 106 and second layers 108 may include different materials, different constituent atomic percentages, different constituent weight percentages, and/or other different characteristics to achieve desired etching selectivity.

In the present embodiment, the first layers 106 may include silicon (Si) and the second layers 108 may include silicon germanium (SiGe), which has a different etch selectivity than silicon. Although non-limiting, a thickness of each first layer 106 may be about 1 nm to about 10 nm, a thickness of each second layer 108 may be about 1 nm to about 10 nm, and the two thicknesses can be the same or different. Although non-limiting, the plurality of alternating first layers 106 and second layers 108 may be epitaxially grown in the depicted interleaving and alternating configuration, layer-by-layer, until a desired number of semiconductor layers is reached.

The first and second layers 106, 108 may be processed (e.g., etched) to form a trench 110. The trench 110 may extend to a top surface 112 of the base layer 104, and may have a set of opposing sidewalls 111. The first and second layers 106, 108 may be patterned by any suitable method to form the trench 110. For example, the nanosheet stack 102 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. Embodiments herein are not limited in this context.

According to an exemplary embodiment, the base layer 104 may be a bulk semiconductor substrate. As used herein, the term “bulk semiconductor substrate” refers to a substrate in which the entirety of the substrate is comprised of a semiconductor material. The bulk semiconductor substrate may comprise any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In some embodiments, the semiconductor material is silicon (Si). In one or more embodiments, the base layer 104 may include a semiconductor material, e.g., silicon (Si), carbon (C), germanium (Ge), silicon germanium (SiGe), germanium tin (GeSn), other semiconductor materials, or any combination thereof. In one or more embodiments, the base layer 104 may include one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In some embodiments, the semiconductor material may be a doped material, such as n-doped silicon (n-Si), or p-doped silicon (p-Si). In some embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. In one or more embodiments, the dopant is selected from one or more of boron (B), gallium (Ga), phosphorus (P), arsenic (As), other semiconductor dopants, or combinations thereof.

A gate structure 114 (e.g., dummy gate) may also be formed over the first layers 106 and the second layers 108, on opposite sides of the trench 110. The gate structure 114 may include a sacrificial gate having a gate material layer and an interlayer dielectric (ILD) 117 formed atop the gate material layer. In some embodiments, the gate material layer may be an amorphous silicon (a-Si) or a polysilicon.

A lateral selective etch may be performed to trim the second layers 108 horizontally (e.g., by a few nm) to form gaps between Si nanosheets. One or more low-k materials may then be used to fill these gaps and form an inner spacer 120. In various non-limiting embodiments, low-k materials may include a dielectric having a dielectric constant less than about 7, for example, less than about 5 or even less than about 2.5, such as carbon containing silicon materials such as silicon oxycarbides (SiOC) or silicon carbides, silicon nitrides (SiN) or carbon containing silicon nitride materials (SiCN), and/or boron nitride (BN), silicon boron nitride (SiBN), silicon boron carbide nitride (SiBCN), carbon doped silicon oxide, fluorine doped oxide, porous dielectric, or combinations thereof. As shown, the inner spacer 120 is generally formed along an exposed sidewall surface of each of the second layers 108.

As shown in FIG. 1B, a source/drain (S/D) material 124 may be formed within the trench 110. In the embodiment shown, the S/D material 124 may be formed using an epitaxy process such as chemical vapor deposition (CVD) techniques (e.g., vapor phase epitaxy and/or Ultra-High Vacuum CVD), molecular beam epitaxy, other suitable epitaxial growth processes, or combinations thereof, to form the S/D material 124. The epitaxy process can use gaseous and/or liquid precursors.

As shown in FIG. 1C, a mask layer 126 may be formed over the gate structure 114 and atop an upper surface 128 of the S/D material 124, and an opening 130 may then be formed through the S/D material 124. The opening 130 may be etched selective to the upper surface 112 of the base layer 104. As shown, only a portion of the S/D material 124 is removed, leaving a S/D epitaxial layer 132 along each sidewall 111 of the trench 110. The S/D epitaxial layer 132 may be in contact with the first layers 106 and the inner spacer 120.

As shown in FIG. 1D, a recess 134 may be formed in the base layer 104, between the S/D epitaxial layers 132. In some embodiments, the recess 134 may be formed by dry/anisotropically etching the upper surface 112 of the base layer 104 within the opening 130. A temporary material 135 may then be formed within the recess 134, as shown in FIG. 1E. Although non-limiting, the temporary material 135 may be a dummy fill formed to be approximately co-planar with the upper surface 112 of the base layer 104.

In some embodiments, as shown in FIG. 1F, the S/D epitaxial layer 132 may be doped using an in-situ process (i.e., doped during deposition by adding impurities to a source material of the epitaxy process) or an ex-situ process (e.g., doped by an ion implantation process subsequent to a deposition process). For example, one or more implant processes may be performed whereby ions 133 are directed into the S/D epitaxial layer 132 including into an exposed, inner surface of the S/D epitaxial layer 132. Although non-limiting, the ions 133 may include p-type or n-type species depending on whether the nanosheet stack 102 is nGAA or pGAA, for example. The ions 133 may be further directed into the inner spacer 120. In some embodiments, the implant is performed at room temperature (e.g., 15-30° C.) or greater.

In this embodiment, the implant process may be a plasma treatment, e.g., plasma doping (PLAD) or decoupled plasma treatment (DPX), which impacts the nanosheet stack 102, including the S/D epitaxial layer 132. In various embodiments, the implant process may be delivered at a substantially horizontal angle relative to the nanosheet stack 102, as shown, and/or vertically. As such, the ions 133 may simultaneously impact the temporary material 135 and the S/D epitaxial layers 132. Although non-limiting, the implant process may be constant or variable.

As shown in FIG. 1G, a thermal process (e.g., rapid thermal anneal) 138 may be performed after the implant process to activate the dopants, particularly along the exposed inner surface of the S/D epitaxial layer 132. This area of increased dopant activation is demonstrated as metal sidewall (MSW) contact layer 142 within the opening 130. As a result of the implantation and thermal processes, Rc may be minimized for the sidewalls of the trench 110.

In other embodiments, the thermal treatment to activate the dopants may be achieved via one or more subsequent front end of the line (FEOL) thermal processing steps. In yet other embodiments, a first thermal treatment may be performed immediately following the implant process and a second thermal treatment may occur during one or more FEOL processes.

As shown in FIG. 1H, a metal 144 may then be deposited within the trench 110, adjacent the MSW contact layer 142. The metal 144 may extend between the temporary material 135 and the upper surface 128 of the S/D epitaxial layer 132. As a result of the previously performed implant and thermal processes, resistance is lower at the interface between the metal 144 and the S/D epitaxial layer 132. Although non-limiting, the metal 144 may be, or comprise, cobalt, tungsten, copper, ruthenium, alloys thereof, or a combination thereof, and may be deposited by CVD, ALD, PVD, or another deposition technique. A dielectric layer 146 may then be formed over the metal 144.

As shown in FIG. 1I, the device 100 may be flipped and the base layer 104 thinned (e.g., etched or planarized). Advantageously, the temporary material 135 acts as an etch stop layer, and the base layer 104 is removed selective to the temporary material 135, with good uniformity.

As shown in FIG. 1J, the temporary material 135 may be removed from the recess 134 using, e.g., a wet etch. In some embodiments, the wet etch exposes an upper surface 147 of the metal 144. A second metal 150 may then be formed in the recess 134, as shown in FIG. 1K, to form a backside contact 152. In some embodiments, the second metal 150 may deposited over the base layer 104, including atop the metal 144 within the recess 134, and then partially removed (e.g., planarized). Although non-limiting, the second metal 150 may be the same or different as metal 144, and may comprise, cobalt, tungsten, copper, ruthenium, alloys thereof, or a combination thereof, and may be deposited by CVD, ALD, PVD, or another deposition technique.

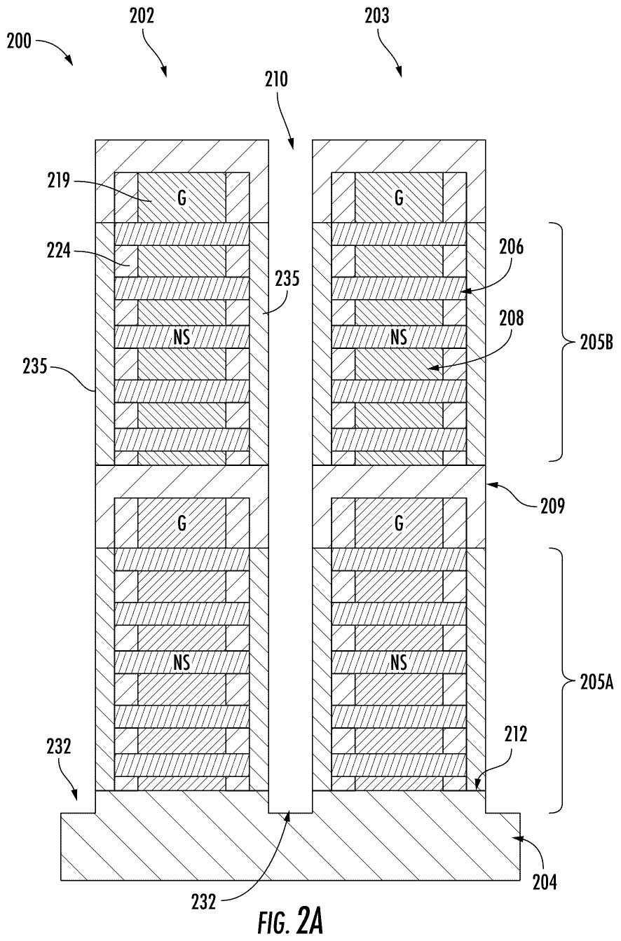

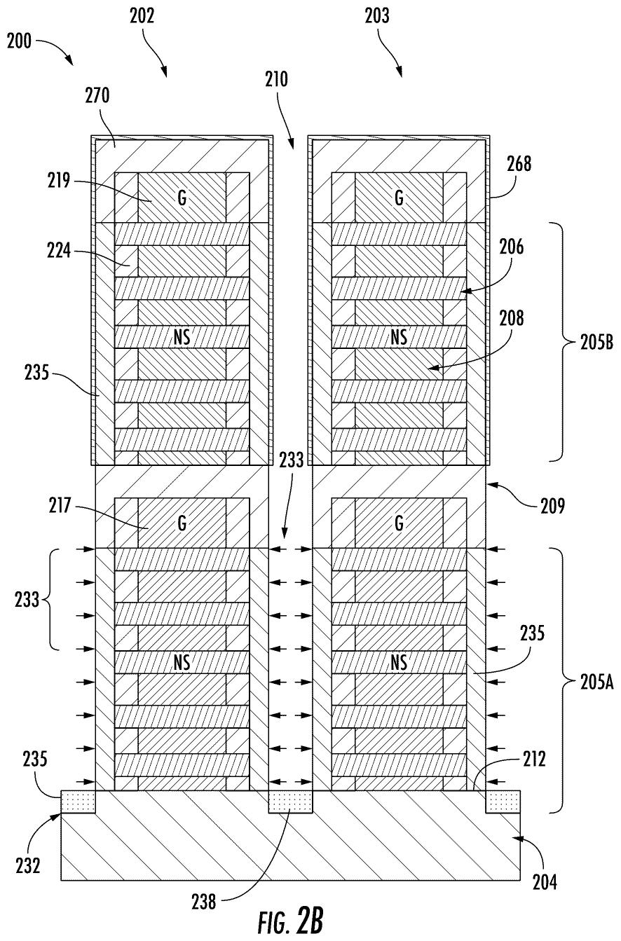

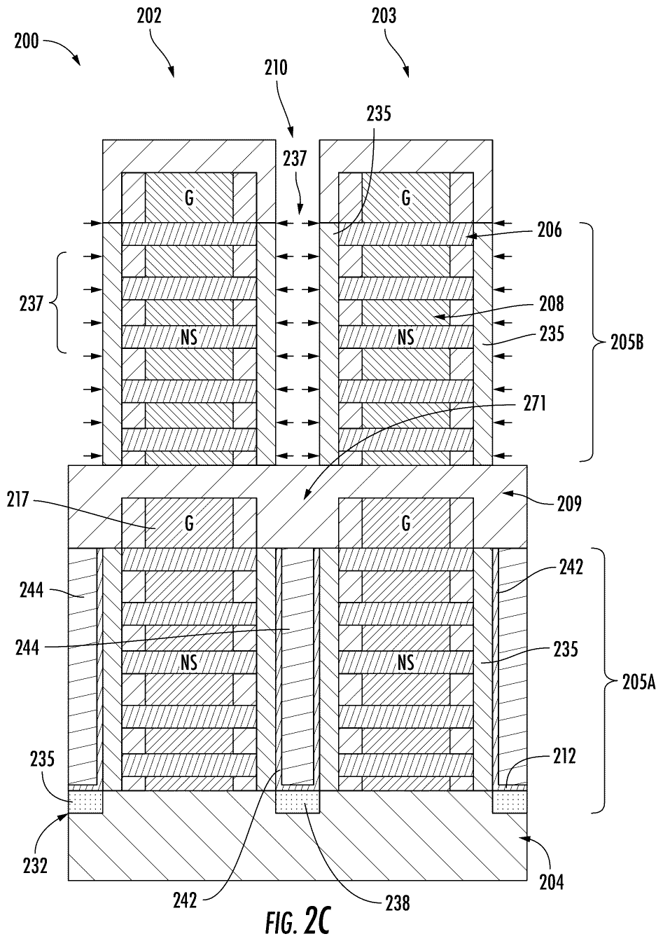

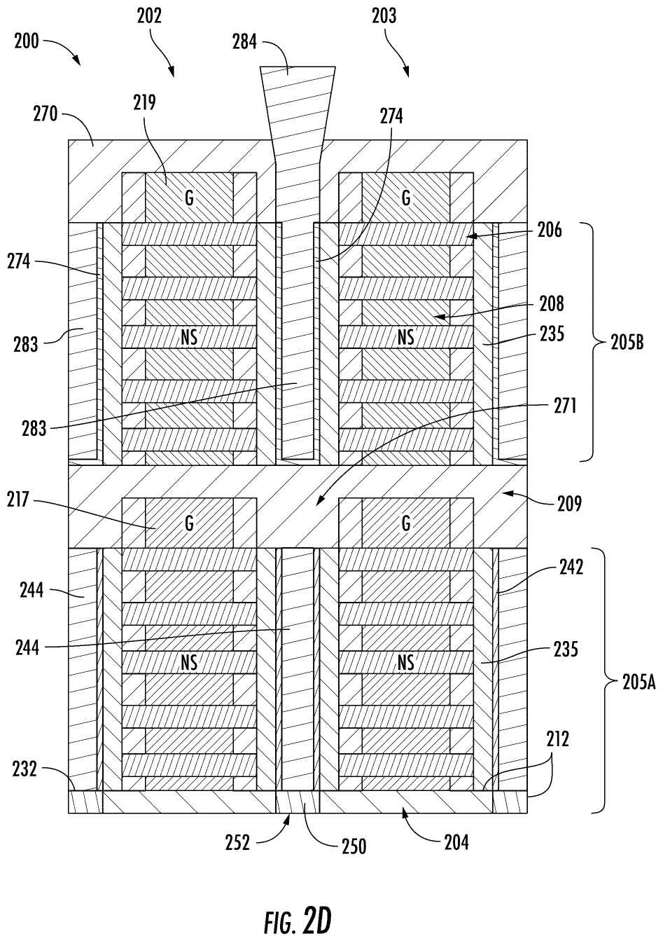

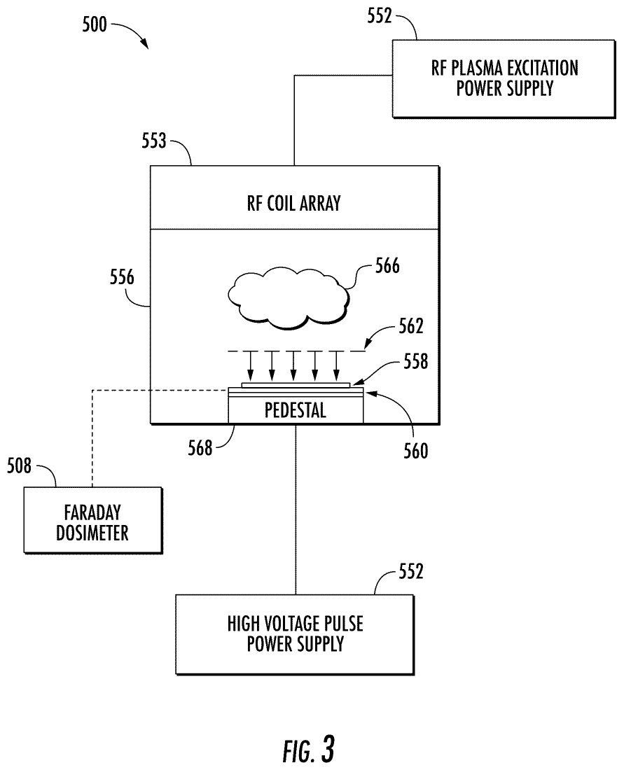

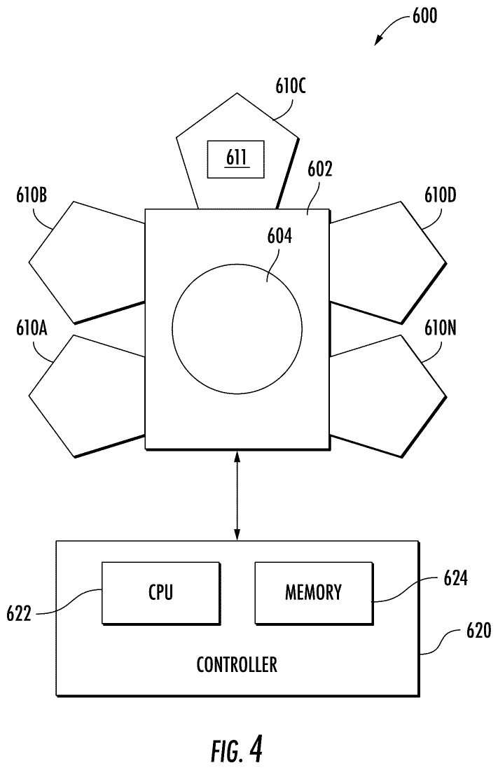

Turning to FIG. 2A, an approach for forming another semiconductor device (hereinafter “device”) 200 according to one or more embodiments will be described. As shown, the device 200 may include a first stack 202 and a second stack 203 separated by a trench 210, each of the first and second stacks 202, 203 including a plurality of alternating first layers 206 and second layers 208 formed over a base layer 204. The plurality of alternating first layers 206 and second layers 208 may be arranged as a lower portion 205A separated from an upper portion 205B by a middle dielectric layer 209 and a set of gates 217.

As arranged, the device 200 may be a CFET having a pNS beneath an nNS. More specifically, the lower portion 205A of first and second stacks 202, 203 may form a device of a first polarity, i.e., a PFET or an NFET, and the upper portion 205B of the first and second stacks 202, 203 may form a device of a second/opposite polarity, i.e., an NFET if the lower portion 205A is a PFET, or vice versa. Due to this top-bottom arrangement, a large aspect ratio is present in trench 210, for which a conventional beam-line ion implant is inadequate due to shadowing effect. As such, a PLAD process is beneficial to deliver ions to the sidewalls of the first stack 202 and the second stack 203, as will be described in greater detail below.

Each of the stacks 202, 203 may include a set of opposing sidewall surfaces upon which a S/D epitaxial layer 235 may be formed. As shown, the S/D epitaxial layer 235 may be a material layer extending continuously from an upper surface 212 of the base layer 204 to a gate 219 of the stacks 202, 203. As shown, S/D epitaxial layer 235 may be in direct contact with the first layers 206 and with inner spacers 224.

As further shown, a plurality of recesses 232 may be formed in the base layer 204. The recesses 232 may be formed using an anisotropic etch to extend the trench 210 beneath the upper surface 212 of the base layer 204. The recesses 232 may then be filled with a temporary material 238, as shown in FIG. 2B. Although non-limiting, the temporary material 238 may be a dummy fill formed to be approximately co-planar with the upper surface 212 of the base layer 204.

As further shown in FIG. 2B, the upper portion 205B of the first and second stacks 202, 203 may include a dielectric liner 268 formed over exterior surfaces thereof. More specifically, the dielectric liner 268 may be formed atop an interlayer dielectric 270 and along the S/D epitaxial layer 235. As shown, the dielectric liner 268 may not be formed along the middle dielectric layer 209 or along the lower portion 205A of the first and second stacks 202, 203.

In some embodiments, the first and second stacks 202, 203 may be doped using one or more implant processes in which ions 233 are directed into an exterior surface of the S/D epitaxial layer 235 formed along the lower portion 205A. The dielectric liner 268 may reduce impact of the ions 233 to the S/D epitaxial layer 235 formed along the upper portion 205B. Although non-limiting, the ions 233 may include p-type or n-type species, and may be performed at room temperature or greater. In this embodiment, the implant process may be a plasma treatment, which is followed by a thermal process (e.g., anneal) operable to activate the dopants, particularly along the exterior surface(s) of the S/D epitaxial layer 235 in the lower portion 205A. This area of increased dopant activation is demonstrated as layer 242 in FIG. 2C.

As shown in FIG. 2C, a metal 244 may then be formed over the lower portion 205A of the first stack 202 and the second stack 203, including within the trench 210. In some embodiments, the metal 244 may be formed atop the upper surface 212 of base layer 204 and along the layer 242.

Next, as further shown in FIG. 2C, a middle dielectric layer 271 may be formed atop the metal 244, within the trench 210, and the dielectric liner 268 may be removed from the first and second stacks 202, 203. The first and second stacks 202, 203 are then doped using one or more implant processes in which ions 237 are directed into an exterior surface of the S/D epitaxial layer 235 of the upper portion 205B. The implant process may be a plasma treatment, which is followed by a thermal process (e.g., anneal) operable to activate the dopants, particularly along the exterior surface(s) of the S/D epitaxial layer 235 of the upper portion 205B. This area of increased dopant activation is demonstrated as layer 274 in FIG. 2D.

As further shown in FIG. 2D, a second metal 283 may be formed along the stacks 202, 203 of the upper portion 205B, including within the trench 210. The second metal 283 may be deposited directly atop the interlayer dielectric 270 and over layer 274, which extends along the S/D epitaxial layer 235. As shown, the second metal 283 may form a frontside contact 284, which extends through an opening of the interlayer dielectric 270.

To process the backside of the device 200 and form a self-aligned contact, the device 200 may be flipped and the base layer 204 thinned (e.g., etched or planarized), wherein the temporary material 238 acts as an etch stop layer. The base layer 204 is removed selective to the temporary material 238, with good uniformity.

The temporary material 238 may then be removed from the recesses 232 using, e.g., a wet etch. In some embodiments, the wet etch exposes the metal 244 of the lower portion 205A. A second metal 250 may then be formed in the recesses 232, as shown, to form a backside contact 252. In some embodiments, the second metal 250 may deposited over the base layer 204, including directly atop the metal 244, and then partially removed (e.g., planarized). Although non-limiting, the second metal 250 may be the same or different as metal 244, and may comprise cobalt, tungsten, copper, ruthenium, alloys thereof, or a combination thereof, and may be deposited by CVD, ALD, PVD, or another deposition technique.

Referring to FIG. 5, an example system 500 (e.g., a PLAD system) operable to provide pulsed RF-excited continuous plasma doping to the devices 100, 200 described herein. As shown, the system 500 may include a plasma power supply 503, a voltage pulse power supply 504, an RF coil array 506, and a dosimeter 508. Within a plasma chamber 510 is a wafer/substrate 502, which may be the same or similar to the substrate base described above. A platen/pedestal 514 may support the wafer 502, and a sheath 518 may be formed above the wafer 502. A temperature of the platen/pedestal 514 may be elevated (e.g., to 300° C. or greater) during plasma doping. In other embodiments, the platen/pedestal 514 may be maintained at room temperature during plasma doping. The dosimeter 508 may be a Faraday dosimeter or other type of sensor that directly measures the dose of ions received by the wafer 502. Although non-limiting, the dosimeter can be located on the pedestal 514, proximate to the wafer 502.

During use, the plasma power supply 503 and the RF coil array 506 deliver radio frequency excitation to generate a plasma 525 when gaseous species are delivered into the plasma chamber 510. For example, the plasma power supply 503 may be an RF powered inductively coupled power source to generate inductively coupled plasma 525, as known in the art. Gaseous species may be delivered from one or more gas sources (not separately shown) to generate ions of any suitable species, such as boron.

The voltage pulse power supply 504 may generate a bias voltage between the wafer 502 and the plasma chamber 510. As such, when the voltage pulse power supply 504 generates a voltage between the plasma chamber 510 and the substrate 502, a similar, but slightly larger, voltage difference is generated between the plasma 525 and the substrate 502. In one non-limiting example, a 5000 (5 kV) voltage difference established between the plasma chamber 510 and the substrate 502 (or, equivalently, pedestal 514) may generate a voltage difference of approximately 5005 V to 5030 V between the plasma 525 and the substrate 502.

In some embodiments, the voltage pulse power supply 504 may generate a bias voltage as a pulsed voltage signal, wherein the pulsed voltage signal is applied in a repetitive and regular manner, to generate a pulse routine comprising a plurality of extraction voltage pulses. For example, a pulse routine may apply voltage pulses of 500 V magnitude, 1000 V magnitude, 2000 V magnitude, 5000 V magnitude, or 10,000 V magnitude in various non-limiting embodiments. The system 500 may further include a controller (not shown), to control the pulsing routine applied to the substrate 502, in order to provide the sidewall doping.

According to various embodiments, the plasma 525 may be formed at least in part of ions that constitute an amorphizing species, wherein the amorphizing species may be any suitable ion capable of amorphizing an initially crystalline region of materials, such as the substrate 502. In various non-limiting embodiments, such suitable ions may include boron. When the plasma 525 is present in the plasma chamber 510, the controller may generate a signal for the voltage pulse power supply 504 to apply a pulse routine to the substrate 502, where the pulse routine constitutes a plurality of extraction voltage pulses. As such, when the extraction voltage pulses are applied between the substrate 502 and plasma 525, ions are extracted in pulsed form from the plasma 525, generating a plurality of ion pulses that are directed to the substrate 502.

FIG. 6 shows a schematic of another example apparatus/system 600 according to embodiments of the disclosure. In some embodiments, the system 600 may be a cluster tool operable to perform processes necessary to form the devices 100, 200 described herein. Although non-limiting, the system 600 may include at least one central transfer station/chamber 602 and one or more robots 604 within the transfer station/chamber 602, wherein the robot 604 is operable to move a robot blade and a wafer to and from each of a plurality of processing chambers 610A-610N connected with, or positioned adjacent to, the transfer station/chamber 602. In some embodiments, the processing chambers 610A-610N may support angled beamline ion implantation, material deposition, and material etching. The particular arrangement of process chambers and components can be varied depending on the cluster tool, and should not be taken as limiting the scope of the disclosure. In another example, one or more of the chambers may include multiple process regions within a same chamber, which permits a common supply of gases, common pressure control, and common process gas exhaust/pumping. Modular design of the system enables rapid conversion from one configuration to any other.

In some embodiments, processing chamber 610A may be a deposition chamber, processing chamber 610B may be an etch chamber, and processing chamber 610C may house an ion processing tool 611 operable to perform the implant process in which ions are directed into the stacks of layers, as described herein with respect to devices 100 and 200. In some embodiments, the ion processing tool 611 may be a PLAD tool. In some embodiments, processing chamber 610D may be operable to perform one or more thermal processes, such as an anneal to the devices 100 and 200.

A system controller 620 is in communication with the robot 604, the transfer station/chamber 602, and the plurality of processing chambers 610A-610N. The system controller 620 can be any suitable component that can control the processing chambers 610A-610N and robot(s) 604, as well as the processes occurring within the process chambers 610A-610N. For example, the system controller 620 can be a computer including a central processing unit 622, memory 624, suitable circuits/logic/instructions, and storage.

Processes or instructions may generally be stored in the memory 624 of the system controller 620 as a software routine that, when executed by the processor 622, causes the processing chambers 610A-610N to perform processes of the present disclosure. The software routine may also be stored and/or executed by a second processor (not shown) that is remotely located from the hardware being controlled by the processor 622. Some or all of the method(s) of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor 622, transforms the general-purpose computer into a specific purpose computer (controller) that controls the chamber operation such that the processes are performed.

In various embodiments, design tools can be provided and configured to create the datasets used to pattern the semiconductor layers of the device, e.g., as described herein. For example, data sets can be created to generate photomasks used during lithography operations to pattern the layers for structures as described herein. Such design tools can include a collection of one or more modules and can also be comprised of hardware, software or a combination thereof. Thus, for example, a tool can be a collection of one or more software modules, hardware modules, software/hardware modules or any combination or permutation thereof. As another example, a tool can be a computing device or other appliance running software, or implemented in hardware.

For the sake of convenience and clarity, terms such as “top,” “bottom,” “upper,” “lower,” “vertical,” “horizontal,” “lateral,” and “longitudinal” will be used herein to describe the relative placement and orientation of components and their constituent parts as appearing in the figures. The terminology will include the words specifically mentioned, derivatives thereof, and words of similar import.

As used herein, an element or operation recited in the singular and proceeded with the word “a” or “an” is to be understood as including plural elements or operations, until such exclusion is explicitly recited. Furthermore, references to “one embodiment” of the present disclosure are not intended as limiting. Additional embodiments may also incorporate the recited features.

Furthermore, the terms “substantial” or “substantially,” as well as the terms “approximate” or “approximately,” can be used interchangeably in some embodiments, and can be described using any relative measures acceptable by one of ordinary skill in the art. For example, these terms can serve as a comparison to a reference parameter, to indicate a deviation capable of providing the intended function. Although non-limiting, the deviation from the reference parameter can be, for example, in an amount of less than 1%, less than 3%, less than 5%, less than 10%, less than 15%, less than 20%, and so on.

Still furthermore, one of ordinary skill will understand when an element such as a layer, region, or substrate is referred to as being formed on, deposited on, or disposed “on,” “over” or “atop” another element, the element can be directly on the other element or intervening elements may also be present. In contrast, when an element is referred to as being “directly on,” “directly over” or “directly atop” another element, no intervening elements are present.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Furthermore, the present disclosure has been described herein in the context of a particular implementation in a particular environment for a particular purpose. Those of ordinary skill in the art will recognize the usefulness is not limited thereto and the present disclosure may be beneficially implemented in any number of environments for any number of purposes. Thus, the claims set forth below are to be construed in view of the full breadth and spirit of the present disclosure as described herein.

What is claimed is:

1. A method, comprising:
forming a plurality of alternating first layers and second layers atop a base layer;
forming a trench in the plurality of alternating first layers and second layers;
forming a source/drain epitaxial layer along a sidewall of the trench;
forming a recess in the base layer by extending the trench into the base layer following formation of the source/drain epitaxial layer;
filling the recess with a temporary material; and
performing an implant by directing ions to the source/drain epitaxial layer after filling the recess with the temporary material, wherein the implant increases an ion concentration along a surface of the source/drain epitaxial layer.

2. The method of claim 1, further comprising performing a thermal process on the plurality of alternating first layers and second layers and on the source/drain epitaxial layer after performing the implant.

3. The method of claim 1, further comprising depositing a metal over the alternating first layers and second layers, including within the trench.

4. The method of claim 3, further comprising forming a dielectric layer over the metal.

5. The method of claim 4, wherein forming the plurality of alternating first layers and second layers atop the base layer comprises:
forming a lower portion of the plurality of alternating first layers and second layers;
forming the dielectric layer atop the lower portion of the plurality of alternating first layers and second layers;
forming, atop the dielectric layer, an upper portion of the plurality of alternating first layers and second layers.

6. The method of claim 4, further comprising:
removing the base layer selective to the temporary material;
removing the temporary material from the recess; and
depositing a second metal within the recess to form a contact.

7. The method of claim 1, further comprising:
forming an inner spacer layer along the trench in the plurality of alternating first layers and second layers;
depositing a source/drain material within the trench following formation of the inner spacer; and
removing a portion of the source/drain material to form the source/drain epitaxial layer along the sidewall of the trench.

8. The method of claim 1, wherein performing the implant comprises performing a plasma doping process.

9. A method for forming a backside contact in a semiconductor device, the method comprising:
forming a trench in a plurality of alternating first layers and second layers, wherein the plurality of alternating first layers and second layers are formed atop a base layer;
forming a source/drain epitaxial layer along a sidewall of the trench, wherein the source/drain epitaxial layer is in contact with one or more of the plurality of alternating first layers and second layers;
forming a recess in the base layer by extending the trench into the base layer following formation of the source/drain epitaxial layer;
filling the recess with a temporary material;
performing an implant by directing ions to the source/drain epitaxial layer after filling the recess with the temporary material, wherein the implant increases an ion concentration along an outer surface of the source/drain epitaxial layer;
removing the temporary material from the recess; and
depositing a contact material within the recess to form the backside contact.

10. The method of claim 9, further comprising performing a thermal process on the plurality of alternating first layers and second layers and on the source/drain epitaxial layer after performing the implant.

11. The method of claim 9, further comprising depositing a metal over the alternating first layers and second layers, including within the trench, following the implant.

12. The method of claim 11, further comprising forming a dielectric layer over the metal.

13. The method of claim 12, wherein forming the plurality of alternating first layers and second layers atop the base layer comprises:
forming a lower portion of the plurality of alternating first layers and second layers;
forming the dielectric layer atop the lower portion of the plurality of alternating first layers and second layers;
forming, atop the dielectric layer, an upper portion of the plurality of alternating first layers and second layers.

14. The method of claim 4, further comprising removing the base layer selective to the temporary material prior to removing the temporary material from the recess.

15. The method of claim 9, further comprising:
forming an inner spacer layer along the trench in the plurality of alternating first layers and second layers;
depositing a source/drain material within the trench following formation of the inner spacer; and
removing a portion of the source/drain material to form the source/drain epitaxial layer along the sidewall of the trench.

16. The method of claim 9, wherein performing the implant comprises performing a plasma doping process.

17. A method, comprising:
forming a trench in a nanosheet stack, the nanosheet stack comprising a plurality of alternating first layers and second layers;
forming a source/drain epitaxial layer along a sidewall of the trench;
etching a bottom of the trench to form a recess in the base layer following formation of the source/drain epitaxial layer;
forming a temporary material within the recess; and
performing an implant by directing ions to the source/drain epitaxial layer after forming the temporary material, wherein the implant increases an ion concentration along an outer surface of the source/drain epitaxial layer; and
performing a thermal process on the nanosheet stack and on the source/drain epitaxial layer after performing the implant.

18. The method of claim 17, further comprising:
depositing a metal over the alternating first layers and second layers, including within the trench; and
forming a dielectric layer over the metal.

19. The method of claim 18, wherein forming the plurality of alternating first layers and second layers atop the base layer comprises:
forming a lower portion of the plurality of alternating first layers and second layers;
forming the dielectric layer atop the lower portion of the plurality of alternating first layers and second layers;
forming, atop the dielectric layer, an upper portion of the plurality of alternating first layers and second layers.

20. The method of claim 17, further comprising:
removing the base layer selective to the temporary material;
removing the temporary material from the recess; and
depositing a second metal within the recess to form a contact.
